(19) United States
(12) Patent Application Publication
(10) Pub. No.: US 2026/0338900 A1
(43) Pub. Date: Oct. 29, 2026

(54) Methods and Systems to Reduce Artifacts in Magnetic Resonance Imaging

(71) Applicant: Siemens Healthineers AG, Forchheim (DE)

(72) Inventors: Kun Zhou, Shenzhen (CN); Nan Xiao, Erlangen (DE); Li Yang, Shenzhen (CN)

(73) Assignee: Siemens Healthineers AG, Forchheim (DE)

(21) Appl. No.: 19/662,009

(22) Filed: Apr. 29, 2026

(30) Foreign Application Priority Data
Apr. 29, 2025 (CN) 202510553252.5

(51) Int. Cl. G01R 33/561; G01R 33/48; G01R 33/565

(52) U.S. Cl. CPC G01R 33/5611; G01R 33/482; G01R 33/56545

(57) ABSTRACT

Methods and apparatuses for reducing artifacts in magnetic resonance imaging are described. The method may include: according to a size and a spatial position of each blade in a BLADE sequence used for a formal scan, determining an image subregion corresponding to each blade in an aliasing-free prescan MR image; according to the image subregion corresponding to each blade, obtaining an aliasing-free image corresponding to each blade; according to the aliasing-free image corresponding to each blade, acquiring a GRAPPA kernel corresponding to each blade; acquiring k-space data of each blade acquired during a formal scan of an imaging target; based on the k-space data and the GRAPPA kernel of each blade, obtaining k-space data of each blade after field-of-view expansion; and reconstructing the k-space data of all the blades after field-of-view expansion to obtain a formal scan MR image of the imaging target.

### CROSS REFERENCE TO RELATED APPLICATIONS

This patent application claims priority to, and the benefit of, Chinese Patent Application No. 202510553252.5, filed Apr. 29, 2025, which is incorporated herein by reference in its entirety.

### BACKGROUND

The present disclosure relates to the technical field of medical imaging, in particular to a method and an apparatus that reduce artifacts in MRI, and an MRI system.

In MR (magnetic resonance) imaging, when the size of a defined FOV (field of view) is smaller than the size of an object, a portion of the object outside the FOV may consequently be erroneously mapped into the FOV, thereby causing aliasing artifacts.

Regarding Cartesian imaging, aliasing artifacts typically occur in a phase-encoding direction and a partition-encoding direction, and do not occur in a readout direction, because: in the readout direction, typically oversampling is used without causing a loss in acquisition time, and an additional hardware filter is used to suppress signals outside a readout bandwidth.

However, when a BLADE sequence is used, also called a Periodically Rotated Overlapping ParallEL Lines with Enhanced Reconstruction (PROPELLER) sequence, to perform MR imaging, aliasing artifacts (also called wrap-around artifacts) are more complicated. BLADE imaging is an imaging technique that aims to reduce motion artifacts; it collects data by means of a series of blades rotated around the center of k-space, each blade representing a narrow Cartesian section of k-space, and different blades being obtained by sampling in different phase-encoding directions.

FIG. 1 is a schematic drawing of blades acquired in two phase-encoding directions PE1 and PE2 when a conventional BLADE sequence is used for MR imaging. As shown in FIG. 1, there are two blades, which respectively correspond to the phase-encoding directions PE1 and PE2; the regions inside the blue and orange boxes are the FOV. It can be seen that the orange blade sampled in the phase-encoding direction PE2 exceeds the FOV, and two black circular aliasing artifacts appear in this blade, which are formed by two gray circular regions outside the FOV wrapping into the FOV; this type of aliasing artifact propagates throughout k-space, affecting the quality of the final reconstructed image.

It has been discovered through practice that using a BLADE sequence to perform MR imaging more easily generates aliasing artifacts. At present, a method that adjusts a scanning parameter is typically used to reduce aliasing artifacts in BLADE imaging, such as increasing the FOV, or using phase oversampling, or using a saturation band to suppress signals originating outside the FOV. However, these methods all have individual defects, wherein: increasing the FOV may reduce image resolution, and a longer scan time may be necessary to maintain resolution; using phase oversampling also results in a longer scan time; and using a saturation band requires a slightly longer measurement time, and may increase an SAR (specific absorption rate).

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a schematic drawing of blades acquired in two phase-encoding directions when a conventional BLADE sequence is used for MR imaging;

FIG. 2 is a flowchart of a method that reduces artifacts in MR imaging provided according to exemplary embodiments of the present disclosure;

FIG. 3 is a schematic drawing of an aliasing-free image corresponding to a blade obtained according to an aliasing-free two-dimensional prescan MR image, according to exemplary embodiments;

FIG. 4 is a schematic drawing of a process that reduces artifacts in MR imaging according to exemplary embodiments of the present disclosure;

FIG. 5 shows comparisons of k-space data and image data of two example blades before and after an FOV is expanded, according to exemplary embodiments;

FIG. 6 shows comparative schematic drawings of BLADE imaging performed using the conventional techniques and according to exemplary embodiments of the present disclosure;

FIG. 7 is a structural schematic drawing of an apparatus that reduces artifacts in MR imaging according to exemplary embodiments of the present disclosure.

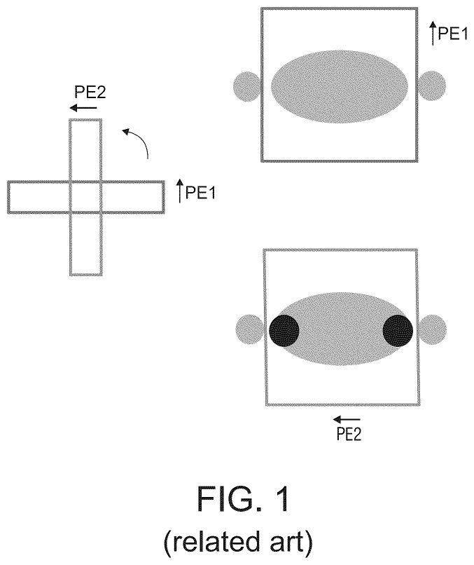

The exemplary embodiments of the present disclosure will be described with reference to the accompanying drawings. Elements, features and components that are identical, functionally identical and have the same effect are-insofar as is not stated otherwise respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

In view of this, one aspect of embodiments of the present disclosure proposes a method and an apparatus that reduces artifacts in MR imaging, to reduce artifacts in BLADE imaging; another aspect of the embodiments of the present disclosure proposes an MR imaging system, to reduce artifacts in BLADE imaging.

A method that reduces artifacts in magnetic resonance imaging, the method comprising:
acquiring an aliasing-free prescan MR image of an imaging target;
according to a size and a spatial position of each blade in a BLADE sequence used subsequently for a formal scan, finding an image subregion corresponding to each blade in the aliasing-free prescan MR image;
in the aliasing-free prescan MR image, according to the image subregion corresponding to each blade, obtaining an aliasing-free image corresponding to each blade;
according to the aliasing-free image corresponding to each blade, acquiring a Generalized Autocalibrating Partially Parallel Acquisitions (GRAPPA) kernel corresponding to each blade;
acquiring k-space data of each blade acquired during a formal scan of the imaging target;
for the k-space data of each blade acquired during the formal scan, using the k-space data of this blade and the GRAPPA kernel of this blade to obtain k-space data of this blade after field-of-view expansion; and
reconstructing the k-space data of all the blades after field-of-view expansion, to obtain a formal scan MR image of the imaging target.

The step of according to a size and a spatial position of each blade in a BLADE sequence used subsequently for a formal scan, finding an image subregion corresponding to each blade in the aliasing-free prescan MR image may comprise: for each blade, according to a field of view of this blade, a central point position of this blade, an orientation of this blade and a slice thickness corresponding to this blade used subsequently for a formal scan, finding an image subregion corresponding to this blade in the aliasing-free prescan MR image.

The step of in the aliasing-free prescan MR image, according to the image subregion corresponding to each blade, obtaining an aliasing-free image corresponding to each blade may comprise: for each blade, according to a spatial position of each voxel in this blade, finding a neighborhood of this voxel in the aliasing-free prescan MR image; using a preset interpolation algorithm, performing interpolation on aliasing-free prescan MR image data in this neighborhood to obtain a voxel value of this voxel of this blade; and voxel values of all voxels of this blade forming an aliasing-free image corresponding to this blade.

The step of according to the aliasing-free image corresponding to each blade, acquiring a GRAPPA kernel corresponding to each blade may comprise: respectively performing an inverse Fourier transform on the aliasing-free image corresponding to each blade, to obtain k-space data corresponding to each blade; and according to the k-space data corresponding to each blade, respectively calculating the GRAPPA kernel corresponding to each blade.

After the step of obtaining a formal scan MR image of the imaging target, further: according to an imaging field of view of a current scan used for a formal scan, finding a corresponding image region in the formal scan MR image of the imaging target, the image region acting as a final formal scan MR image of the imaging target.

An apparatus that reduces artifacts in magnetic resonance imaging, the apparatus comprising:
a blade finding module, which acquires an aliasing-free prescan MR image of an imaging target; and according to a size and a spatial position of each blade in a BLADE sequence used subsequently for a formal scan, finds an image subregion corresponding to each blade in the aliasing-free prescan MR image;
an aliasing-free image acquisition module, which in the aliasing-free prescan MR image, according to the image subregion corresponding to each blade, obtains an aliasing-free image corresponding to each blade;
a GRAPPA kernel acquisition module, which according to the aliasing-free image corresponding to each blade, acquires a GRAPPA kernel corresponding to each blade;
a field-of-view expansion module, which acquires k-space data of each blade acquired during the formal scan of the imaging target; and for the k-space data of each blade acquired during the formal scan, uses the k-space data of this blade and the GRAPPA kernel of this blade to obtain k-space data of this blade after field-of-view expansion; and
a reconstruction module, which reconstructs the k-space data of all the blades after field-of-view expansion, to obtain a formal scan MR image of the imaging target.

The blade finding module, according to a size and a spatial position of each blade in a BLADE sequence used subsequently for a formal scan, finding an image subregion corresponding to each blade in the aliasing-free prescan MR image may comprise: for each blade, according to a field of view of this blade, a central point position of this blade, an orientation of this blade and a slice thickness corresponding to this blade used subsequently for a formal scan, finding an image subregion corresponding to this blade in the aliasing-free prescan MR image.

The aliasing-free image acquisition module, in the aliasing-free prescan MR image, according to the image subregion corresponding to each blade, obtaining an aliasing-free image corresponding to each blade may comprise: for each blade, according to a spatial position of each voxel in this blade, finding a neighborhood of this voxel in the aliasing-free prescan MR image; using a preset interpolation algorithm, performing interpolation on aliasing-free prescan MR image data in this neighborhood to obtain a voxel value of this voxel of this blade; and voxel values of all voxels of this blade forming an aliasing-free image corresponding to this blade.

The GRAPPA kernel acquisition module, according to the aliasing-free image corresponding to each blade, acquiring a GRAPPA kernel corresponding to each blade may comprise: respectively performing an inverse Fourier transform on the aliasing-free image corresponding to each blade, to obtain k-space data corresponding to each blade; and according to the k-space data corresponding to each blade, respectively calculating the GRAPPA kernel corresponding to each blade.

After obtaining a formal scan MR image of the imaging target, the reconstruction module further: according to an imaging field of view of a current scan used for a formal scan, finding a corresponding image region in the formal scan MR image of the imaging target, the image region acting as a final formal scan MR image of the imaging target.

A magnetic resonance imaging system, the system comprising any one of the apparatuses that reduces artifacts in MR imaging as described above.

In embodiments of the present disclosure, an image subregion corresponding to each blade used for a formal scan is found in an aliasing-free prescan MR image to obtain an aliasing-free image corresponding to each blade, and then, according to the aliasing-free image corresponding to each blade, a GRAPPA kernel corresponding to each blade is acquired, after which, when a BLADE sequence is used for performing a formal scan and acquiring k-space data of each blade, the k-space data of each blade and the GRAPPA kernel of this blade are used to obtain the k-space data of each blade after FOV expansion, and then the k-space data of all blades after FOV expansion is reconstructed, thereby obtaining a formal scan MR image of the imaging target, so that no manual work is required, the FOV being expanded automatically, so that aliasing artifacts in BLADE imaging are maximally reduced, and the GRAPPA kernel thereof used for FOV expansion is obtained by using a prescan MR image, and therefore additional scan time is not needed, and the process can be seamlessly integrated into an existing scan process.

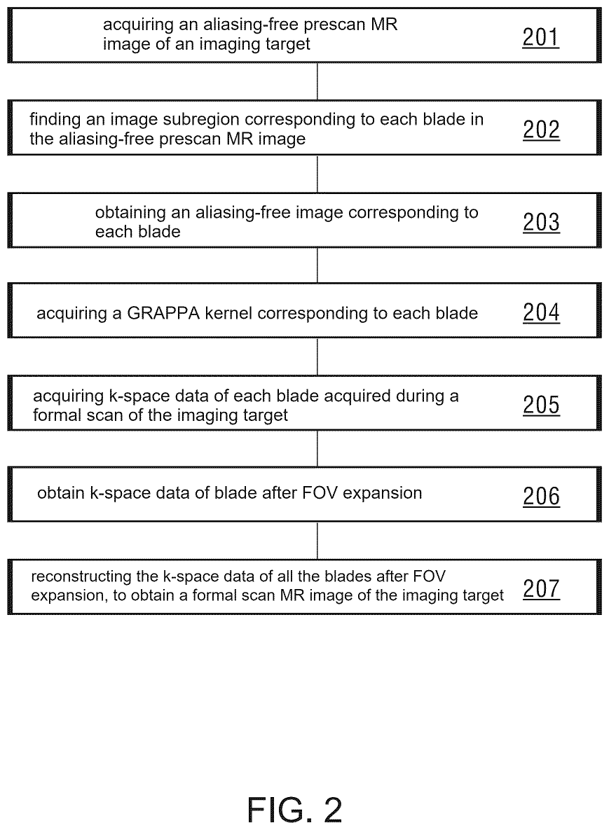

FIG. 2 is a flowchart of a method that reduces artifacts in MR imaging provided in an embodiment of the present disclosure. As shown in FIG. 2, the method may comprise the following steps:

Step 201: acquiring an aliasing-free prescan MR image of an imaging target.

The prescan MR image is obtained by performing image reconstruction on prescan k-space data of the imaging target. The prescan k-space data is k-space data acquired during a prescan of the imaging target.

Typically, multiple prescans are performed before a formal scan of the imaging target; different prescans have different purposes, there being, for example, a prescan for measuring B0 field inhomogeneity, a prescan for measuring B1 field inhomogeneity, a prescan for measuring coil sensitivity, etc. The prescan in step 201 is necessarily a prescan that can obtain an aliasing-free prescan MR image, i.e. a size of an FOV used in this prescan being smaller than a size of the imaging target; in actual applications, a prescan that satisfies this condition is a prescan for measuring coil sensitivity, for example, and characteristics of the prescan for measuring coil sensitivity are using a GRE (gradient echo) sequence, a larger FOV, lower resolution and fast scan speed.

Step 202: according to a size and a spatial position of each blade in a BLADE sequence used subsequently for a formal scan, finding an image subregion corresponding to each blade in the aliasing-free prescan MR image.

The step 202 may comprise: for each blade, according to a field of view of this blade, a central point position of this blade, an orientation of this blade and a slice thickness corresponding to this blade used subsequently for a formal scan, finding an image subregion corresponding to this blade in the aliasing-free prescan MR image.

Step 203: in the aliasing-free prescan MR image, according to the image subregion corresponding to each blade, obtaining an aliasing-free image corresponding to each blade.

The step 203 may comprise: for each blade, according to a spatial position of each voxel in this blade, finding a neighborhood of this voxel in the aliasing-free prescan MR image; using a preset interpolation algorithm, performing interpolation on aliasing-free prescan MR image data in this neighborhood to obtain a voxel value of this voxel of this blade; and voxel values of all voxels of this blade forming an aliasing-free image corresponding to this blade. The interpolation algorithm is not restricted by embodiments of the present disclosure; any existing interpolation algorithm will suffice.

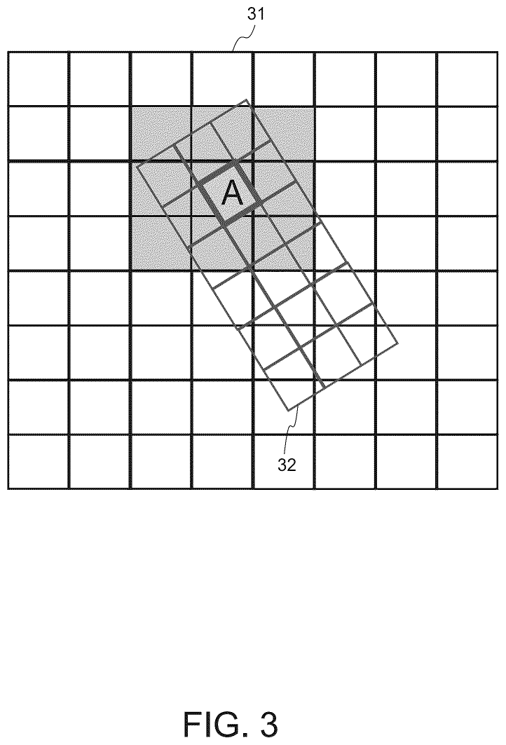

FIG. 3 is a schematic drawing of an aliasing-free image corresponding to a blade obtained according to an aliasing-free two-dimensional prescan MR image. As shown in FIGS. 3, 31 is an aliasing-free two-dimensional prescan MR image, and 32 is a blade in a corresponding image subregion on the aliasing-free two-dimensional prescan MR image. Taking a voxel A on the blade as an example, according to a spatial position of the voxel A, a neighborhood of A is found in the aliasing-free prescan MR image (for example a gray region in the figure), and then an interpolation calculation is performed on voxel values of 9 voxels in the gray region in the aliasing-free prescan MR image, to obtain a voxel value of the voxel A of the blade. Use of the same method can obtain voxel values of other voxels in the blade. In actual applications, an aliasing-free prescan MR image is typically three dimensional. Here, a two-dimensional prescan MR image is described as an example in order to more simply and clearly illustrate the interpolation process. However, as will be appreciated, in actual applications, for an aliasing-free three-dimensional prescan MR image, a blade in a corresponding image subregion on this prescan MR image is a three-dimensional subregion, and a neighborhood of a voxel A used during interpolation is a three-dimensional neighborhood.

Step 204: according to the aliasing-free image corresponding to each blade, acquiring a GRAPPA kernel corresponding to each blade.

The step 204 may comprise: respectively performing an inverse Fourier transform on the aliasing-free image corresponding to each blade, to obtain k-space data corresponding to each blade; and according to the k-space data corresponding to each blade, respectively calculating the corresponding GRAPPA kernel corresponding to each blade. Specifically, a calculation may be performed on the k-space data corresponding to each blade using a GRAPPA kernel algorithm in existing GRAPPA reconstruction algorithms, and then the GRAPPA kernel corresponding to each blade can be obtained.

Step 205: acquiring k-space data of each blade acquired during a formal scan of the imaging target, wherein a BLADE sequence may be used during the formal scan.

Step 206: for the k-space data of each blade acquired during the formal scan, using the k-space data of this blade and the GRAPPA kernel of this blade to obtain k-space data of this blade after FOV expansion.

In an exemplary embodiment, the step of using the k-space data of this blade and the GRAPPA kernel of this blade to obtain k-space data of this blade after FOV expansion may comprise: performing a convolution of the k-space data of this blade and the GRAPPA kernel of this blade, a convolution result being the k-space data of this blade after FOV expansion.

Since the GRAPPA kernel is obtained according to the aliasing-free prescan MR image, and the FOV of the aliasing-free prescan MR image is not smaller than the size of the imaging target, using this GRAPPA kernel to perform a convolution of the k-space data of the blades acquired in a BLADE scan is effectively equivalent to expanding the FOV of the blade.

Step 207: reconstructing the k-space data of all the blades after FOV expansion, to obtain a formal scan MR image of the imaging target.

Specifically, a BLADE reconstruction method may be used to reconstruct the k-space data of all the blades after FOV expansion, to obtain a formal scan MR image of the imaging target.

In an exemplary embodiment, after obtaining a formal scan MR image of the imaging target, step 207 may further comprise: according to an imaging FOV of a current scan used for a formal scan, finding a corresponding image region in the formal scan MR image of the imaging target, and this image region acting as a final formal scan MR image of the imaging target.

In the above embodiment, an image subregion corresponding to each blade used for a formal scan is found in an aliasing-free prescan MR image to obtain an aliasing-free image corresponding to each blade, and then, according to the aliasing-free image corresponding to each blade, a GRAPPA kernel corresponding to each blade is acquired, after which, when a BLADE sequence is used for performing a formal scan and acquiring k-space data of each blade, the k-space data of each blade and the GRAPPA kernel of this blade are used to obtain the k-space data of each blade after FOV expansion, and then the k-space data of all blades after FOV expansion is reconstructed, thereby obtaining a formal scan MR image of the imaging target, so that no manual work is required, the FOV being expanded automatically, so that aliasing artifacts in BLADE imaging are maximally reduced, and the GRAPPA kernel thereof used for FOV expansion is obtained by using a prescan MR image, and therefore additional scan time is not needed, and the process can be seamlessly integrated into an existing scan process.

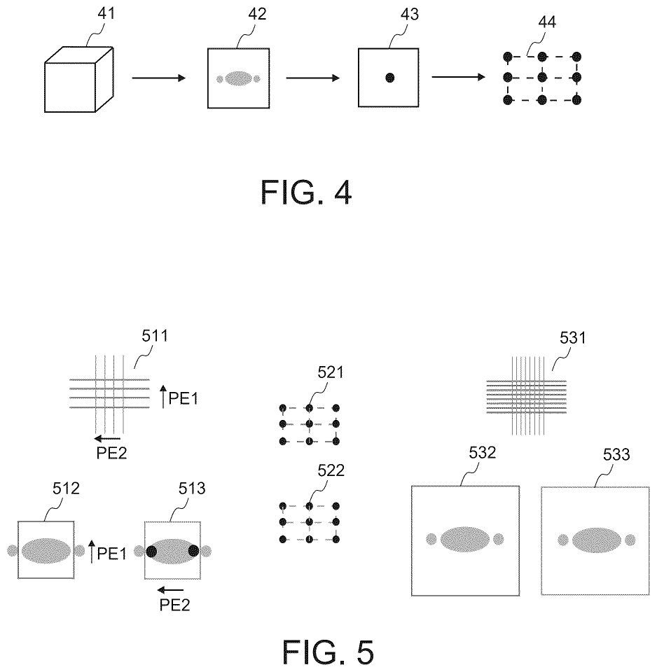

FIG. 4 is a schematic drawing of a process that reduces artifacts in MR imaging in an application embodiment of the present disclosure. As shown in FIGS. 4, 41 is an aliasing-free prescan MR image, 42 is an aliasing-free image corresponding to a blade obtained by performing an interpolation calculation on an image subregion of this blade in 41, 43 is k-space data corresponding to this blade obtained by performing an IFFT (inverse fast Fourier transform) on 42, and 44 is a GRAPPA kernel corresponding to this blade obtained by performing a calculation on 43 using a GRAPPA kernel algorithm in existing GRAPPA reconstruction algorithms.

FIG. 5 shows comparisons of k-space data and image data of two example blades before and after an FOV is expanded. 51 is k-space data and image data of two blades before expanding the FOV, and 52 is k-space data and image data of two blades after expanding the FOV, and the two blades are respectively acquired in phase-encoding directions PE1 and PE2.

Reference number 511 is k-space data of two blades before expanding the FOV, wherein blue lines represent k-space data of the blade in direction PE1, and orange lines represent k-space data of the blade in direction PE2. Reference number 512 represents image data of the blade in direction PE1 before expanding the FOV, a region in a blue box being the FOV before expansion. Reference number 513 represents image data of the blade in direction PE2 before expanding the FOV, a region in an orange box being the FOV before expansion. It can be seen that two black circular aliasing artifacts are present in the FOV of reference number 513, formed by two gray circular regions outside the FOV wrapping into the FOV.

Reference number 521 is a GRAPPA kernel corresponding to the blade in direction PE1, and reference number 522 is a GRAPPA kernel corresponding to the blade in direction PE2.

Reference number 531 is k-space data of two blades after expanding the FOV, wherein blue lines represent k-space data of the blade in direction PE1, and orange lines represent k-space data of the blade in direction PE2. The blue lines and the orange lines in reference number 531 are obtained by performing a convolution of the blue lines and the orange lines in reference number 511 with the GRAPPA kernels 521 and 522 of the two blades. Reference number 532 represents image data of the blade in direction PE1 after expanding the FOV, a region in a blue box being the FOV after expansion. Reference number 533 represents image data of the blade in direction PE2 after expanding the FOV, a region in an orange box being the FOV after expansion. It can be seen that after the FOV is expanded using embodiments of the present disclosure, the image data of the blade in direction PE2 no longer has aliasing artifacts.

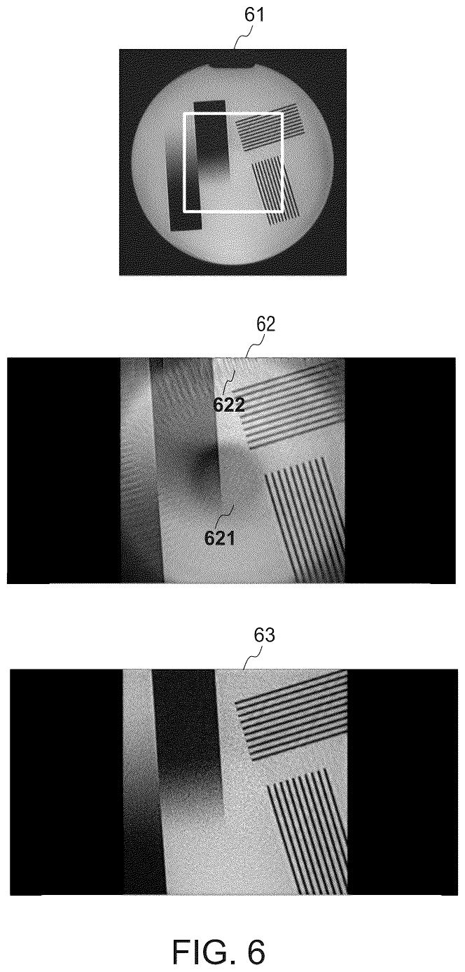

FIG. 6 shows comparative schematic drawings of BLADE imaging performed using conventional techniques and using embodiments of the present disclosure. Reference number 61 is an imaging target, wherein a region in a white box defines an FOV. Reference number 62 is an MR image obtained by performing BLADE imaging using an existing method, and it can be seen that a circular aliasing artifact 621 is present at the center of 62, while aliasing artifacts, such as 622, are also present around the edges. Reference number 63 is an MR image obtained by performing BLADE imaging using a method provided by embodiments of the present disclosure, and it can be seen that no aliasing artifacts are present in 63.

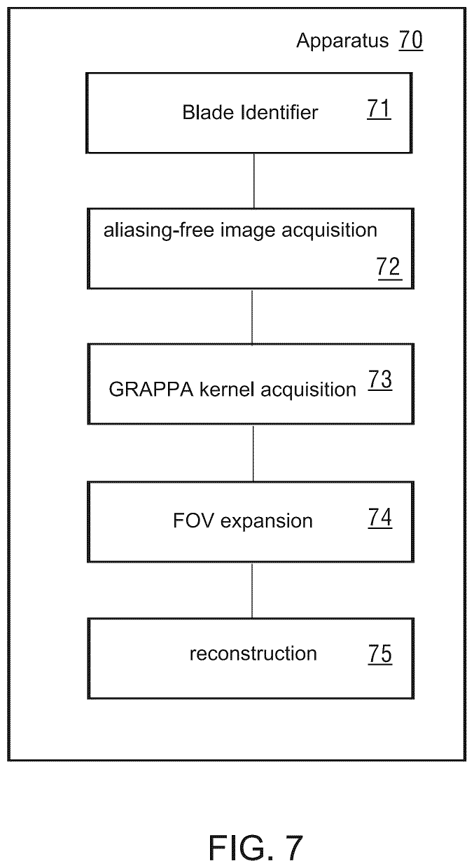

FIG. 7 is a structural schematic drawing of an apparatus 70 that reduces artifacts in MR imaging provided in an embodiment of the present disclosure. As shown in FIG. 7, the apparatus may comprise: a blade finding module (blade identifier) 71, an aliasing-free image acquisition module 72, a GRAPPA kernel acquisition module 73, an FOV expansion module 74 and a reconstruction module 75. The apparatus 70 may include processing circuitry configured to perform one or more functions and/or operations of the apparatus 70. Additionally, or alternatively, one or more components (e.g., 71, 72, 73, 74, 75) of the apparatus 70 may include processing circuitry that is configured to perform one or more respective functions of the component(s). In an exemplary embodiment, one or more components (e.g., 71, 72, 73, 74, 75) may be modules of a memory and including respective instructions, which when executed by one or more processors, performs the corresponding function(s) associated with the module(s).

The blade finding module 71 may acquire an aliasing-free prescan MR image of an imaging target; and according to a size and a spatial position of each blade in a BLADE sequence used subsequently for a formal scan, may identify an image subregion corresponding to each blade in the aliasing-free prescan MR image.

In an exemplary embodiment, the blade finding module 71, according to a size and a spatial position of each blade in a BLADE sequence used subsequently for a formal scan, finding an image subregion corresponding to each blade in the aliasing-free prescan MR image may comprise: for each blade, according to a field of view of this blade, a central point position of this blade, an orientation of this blade and a slice thickness corresponding to this blade used subsequently for a formal scan, finding an image subregion corresponding to this blade in the aliasing-free prescan MR image.

The aliasing-free image acquisition module 72, in the aliasing-free prescan MR image, according to the image subregion corresponding to each blade, obtains an aliasing-free image corresponding to each blade.

In an exemplary embodiment, the aliasing-free image acquisition module 72, in the aliasing-free prescan MR image, according to the image subregion corresponding to each blade, obtaining an aliasing-free image corresponding to each blade may comprise: for each blade, according to a spatial position of each voxel in this blade, finding a neighborhood of this voxel in the aliasing-free prescan MR image; using a preset interpolation algorithm, performing interpolation on aliasing-free prescan MR image data in this neighborhood to obtain a voxel value of this voxel of this blade; and voxel values of all voxels of this blade forming an aliasing-free image corresponding to this blade.

The GRAPPA kernel acquisition module 73, according to the aliasing-free image corresponding to each blade, acquires a GRAPPA kernel corresponding to each blade.

In an exemplary embodiment, the GRAPPA kernel acquisition module 73, according to the aliasing-free image corresponding to each blade, acquiring a GRAPPA kernel corresponding to each blade may comprise: respectively performing an inverse Fourier transform on the aliasing-free image corresponding to each blade, to obtain k-space data corresponding to each blade; and according to the k-space data corresponding to each blade, respectively calculating the corresponding GRAPPA kernel corresponding to each blade.

The FOV expansion module 74 acquires k-space data of each blade acquired during the formal scan of the imaging target; and for the k-space data of each blade acquired during the formal scan, uses the k-space data of this blade and the GRAPPA kernel of this blade to obtain k-space data of this blade after FOV expansion.

The reconstruction module 75 reconstructs the k-space data of all the blades after FOV expansion, to obtain a formal scan MR image of the imaging target.

In an optional embodiment, after obtaining a formal scan MR image of the imaging target, the reconstruction module 75 further: according to an imaging FOV of a current scan used for a formal scan, finding a corresponding image region in the formal scan MR image of the imaging target, and this image region acting as a final formal scan MR image of the imaging target.

Embodiments of the present disclosure further provide an MR imaging system, which may include the apparatus 70 that reduces artifacts in MR imaging as described in any of the above embodiments.

It should be noted that the method and the apparatus that reduce artifacts in MR imaging, and the MR imaging system provided in the embodiments of the present disclosure may all be a method, an apparatus and a system applied in medical imaging.

Embodiments of the present disclosure further provide a computer program product, comprising a computer program or instruction, which, when executed by a processor, implements the steps of the method that reduces artifacts in MR imaging as described in any one of the above embodiments.

Embodiments of the present disclosure further provide a computer-readable storage medium, wherein the computer-readable storage medium stores an instruction, and the instruction, when executed by a processor, can execute the steps of the method that reduces artifacts in MR imaging as described above. In practical applications, the computer-readable medium may be included in each device/apparatus/system in the above embodiments, or may exist independently without being fitted into the device/apparatus/system. An instruction is stored in the computer-readable storage medium, and the instruction stored therein, when executed by a processor, can execute the steps of the method that reduces artifacts in MR imaging as described above.

Embodiments of the present disclosure further provide an electronic device. The electronic device may comprise a processor with one or more processing cores, a memory with one or more computer-readable storage media, and a computer program stored in the memory and executable on the processor. When the program in the memory is executed, the method that reduces artifacts in MR imaging described above may be implemented.

Those skilled in the art will understand that features stated in the various embodiments and/or claims disclosed in the present application can be combined and/or integrated in various ways, even if such combinations or integrations are not clearly stated in the present application. In particular, without departing from the spirit and teaching of the present application, features stated in the various embodiments and/or claims of the present application can be combined and/or integrated in various ways, and all such combinations and/or integrations fall within the scope of disclosure of the present application.

Specific embodiments have been used herein to expound the principles and implementations of the present application, but the description of the embodiments above is merely intended to assist understanding of the method of the present application and the core idea thereof, not to restrict the present application. Those skilled in the art could make changes to specific implementations and scope of application, based on the idea, spirit and principles of the present application, and any changes, equivalent replacements, improvements, etc. made by those skilled in the art should be included within the scope of protection of the present application.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

### REFERENCE LIST

PE1 phase-encoding direction 1
PE2 phase-encoding direction 2
201-207 Steps
31 aliasing-free two-dimensional prescan MR image
32 a blade in a corresponding image subregion on a prescan MR image
A a voxel in 32
41 aliasing-free prescan MR image
42 aliasing-free image corresponding to a blade obtained by performing an interpolation calculation on an image subregion of this blade in 41
43 k-space data corresponding to this blade obtained by performing IFFT on 42
44 Generalized Autocalibrating Partially Parallel Acquisitions (GRAPPA) kernel corresponding to this blade obtained by performing a calculation on 43 using a GRAPPA kernel algorithm in existing GRAPPA reconstruction algorithms
51 k-space data and image data of two blades before expanding FOV
52 k-space data and image data of two blades after expanding FOV
511 k-space data of two blades before expanding FOV
512 image data of blade in direction PE1 before expanding FOV
513 image data of blade in direction PE2 before expanding FOV
521 GRAPPA kernel corresponding to blade in direction PE1
522 GRAPPA kernel corresponding to blade in direction PE2
531 k-space data of two blades after expanding FOV
532 image data of blade in direction PE1 after expanding FOV
533 image data of blade in direction PE2 after expanding FOV
61 imaging target
62 MR image obtained by performing BLADE imaging using an existing method
621 aliasing artifact
622 aliasing artifact
63 MR image obtained by performing BLADE imaging using method provided by embodiments of the present disclosure
70 apparatus that reduces artifacts in MR imaging
71 blade finding module
72 aliasing-free image acquisition module
73 GRAPPA kernel acquisition module
74 FOV expansion module
75 reconstruction module

1. A method for reducing artifacts in magnetic resonance imaging, the method comprises:
acquiring an aliasing-free prescan magnetic resonance (MR) image of an imaging target;
according to a size and a spatial position of each blade in a BLADE sequence used subsequently for a formal scan, determining an image subregion corresponding to each blade in the aliasing-free prescan MR image;
in the aliasing-free prescan MR image, according to the image subregion corresponding to each blade, obtaining an aliasing-free image corresponding to each blade;
according to the aliasing-free image corresponding to each blade, acquiring a Generalized Autocalibrating Partially Parallel Acquisitions (GRAPPA) kernel corresponding to each blade;
acquiring k-space data of each blade acquired during a formal scan of the imaging target;
based on the k-space data of each blade acquired during the formal scan and the GRAPPA kernel of each blade, obtaining k-space data of each blade after field-of-view (FOV) expansion; and
reconstructing the k-space data of all the blades after FOV expansion to obtain a formal scan MR image of the imaging target.

2. The method as claimed in claim 1, wherein determining the image subregion corresponding to each blade in the aliasing-free prescan MR image comprises: for each blade, determining the corresponding image subregion in the aliasing-free prescan MR image based on a FOV, a central point position, an orientation, and a slice thickness of each blade used subsequently for the formal scan.

3. The method as claimed in claim 1, wherein obtaining the aliasing-free image corresponding to each blade comprises:
based on respective spatial positions of each voxel in each blade, determining, for each blade, a neighborhood of each voxel in the aliasing-free prescan MR image;
using a preset interpolation algorithm, performing interpolation on aliasing-free prescan MR image data in the neighborhood to obtain a voxel value of each voxel of each blade; and
forming an aliasing-free image corresponding to each blade based on voxel values of all voxels of each blade.

4. The method as claimed in claim 1, wherein acquiring the GRAPPA kernel corresponding to each blade comprises:
respectively performing an inverse Fourier transform on the aliasing-free image corresponding to each blade, to obtain k-space data corresponding to each blade; and
according to the k-space data corresponding to each blade, respectively calculating the GRAPPA kernel corresponding to each blade.

5. The method as claimed in claim 1, wherein after obtaining the formal scan MR image of the imaging target, the method further comprises:
according to an imaging FOV of a current scan used for the formal scan, determining a corresponding image region in the formal scan MR image of the imaging target, the image region acting as a final formal scan MR image of the imaging target.

6. One or more non-transitory media storing instructions that, when executed by one or more processors, cause the one or more processors to perform the method of claim 1.

7. An apparatus comprising:
one or more processors; and
memory storing instructions that, when executed by the one or more processors, cause the apparatus to perform the method of claim 1.

8. An apparatus adapted to reduce artifacts in magnetic resonance imaging, the apparatus comprising:
a blade identifier configured to: determine an aliasing-free prescan magnetic resonance (MR) image of an imaging target, and, according to a size and a spatial position of each blade in a BLADE sequence used subsequently for a formal scan, determine an image subregion corresponding to each blade in the aliasing-free prescan MR image;
an aliasing-free image acquisition module, which in the aliasing-free prescan MR image, according to the image subregion corresponding to each blade, is configured to obtain an aliasing-free image corresponding to each blade;
a Generalized Autocalibrating Partially Parallel Acquisitions (GRAPPA) kernel acquisition module, which according to the aliasing-free image corresponding to each blade, is configured to acquire a GRAPPA kernel corresponding to each blade;
a field-of-view (FOV) expander configured to: acquire k-space data of each blade acquired during the formal scan of the imaging target, and, based on the k-space data of each blade acquired during the formal scan, use the k-space data of each blade and the GRAPPA kernel of each blade to obtain k-space data of each blade after FOV expansion; and
a reconstructor configured to reconstruct the k-space data of all the blades after FOV expansion to obtain a formal scan MR image of the imaging target.

9. The apparatus as claimed in claim 8, wherein, to determine the image subregion, the blade identifier is configured to:
for each blade, determine the corresponding image subregion in the aliasing-free prescan MR image based on a FOV, a central point position, an orientation, and a slice thickness of each blade used subsequently for the formal scan.

10. The apparatus as claimed in claim 8, wherein, to obtain the aliasing-free image corresponding to each blade, the aliasing-free image acquisition module is configured to:
based on respective spatial positions of each voxel in each blade, determine, for each blade, a neighborhood of each voxel in the aliasing-free prescan MR image;
using a preset interpolation algorithm, perform interpolation on aliasing-free prescan MR image data in the neighborhood to obtain a voxel value of each voxel of each blade; and
form an aliasing-free image corresponding to each blade based on voxel values of all voxels of each blade.

11. The apparatus as claimed in claim 8, wherein, to acquire the GRAPPA kernel corresponding to each blade, the GRAPPA kernel acquisition module is configured to:
respectively perform an inverse Fourier transform on the aliasing-free image corresponding to each blade to obtain k-space data corresponding to each blade; and
according to the k-space data corresponding to each blade, respectively calculate the GRAPPA kernel corresponding to each blade.

12. The apparatus as claimed in claim 8, wherein the reconstructor is configured to: after obtaining the formal scan MR image of the imaging target, according to an imaging FOV of a current scan used for the formal scan, determine a corresponding image region in the formal scan MR image of the imaging target, the image region acting as a final formal scan MR image of the imaging target.

13. A magnetic resonance imaging system comprising the apparatus of claim 8.
